(19) United States
(12) Patent Application Publication
(10) Pub. No.: US 2025/0236760 A1
(43) Pub. Date: Jul. 24, 2025

(54) EPOXY RESIN COMPOSITION FOR ENCAPSULATING SEMICONDUCTOR DEVICE AND SEMICONDUCTOR DEVICE ENCAPSULATED USING THE SAME

(71) Applicant: SAMSUNG SDI CO., LTD., Yongin-si (KR)

(72) Inventors: Dong Hwan LEE, Suwon-si (KR); Tae Shin EOM, Suwon-si (KR); Ki Hyeok KWON, Suwon-si (KR); Min Soo KIM, Suwon-si (KR); Jun Woo LEE, Suwon-si (KR); Kyoung Chul BAE, Suwon-si (KR); Young Joon LEE, Suwon-si (KR)

(21) Appl. No.: 19/018,164

(22) Filed: Jan. 13, 2025

(30) Foreign Application Priority Data
Jan. 23, 2024 (KR) 10-2024-0009879

(51) Int. Cl. C09D 163/00; C08G 59/24; C08K 7/18; C09D 7/40; C09D 7/61; C09K 5/14; H01L 23/29

(52) U.S. Cl. CPC C09D 163/00; C08G 59/245; C09D 7/61; C09D 7/70; C09K 5/14; C08K 7/18; C08K 2201/001; H01L 23/295

(57) ABSTRACT

An epoxy resin composition for encapsulation of semiconductor devices and a semiconductor device encapsulated using the epoxy resin composition, the epoxy resin composition includes an epoxy resin; a curing agent; inorganic fillers; and a curing catalyst, wherein the epoxy resin includes an epoxy resin represented by Formula 1:

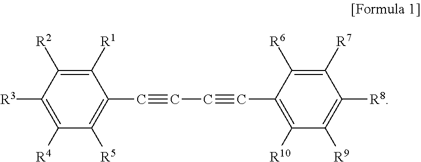

### CROSS-REFERENCE TO RELATED APPLICATION

The present application claims priority and the benefit of Korean Patent Application No. 10-2024-0009879, filed on Jan. 23, 2024 in the Korean Intellectual Property Office, the entire disclosure of which is incorporated herein by reference.

### BACKGROUND

### 1. Field

Embodiments relate to an epoxy resin composition for encapsulation of semiconductor devices and a semiconductor device encapsulated using the same.

### 2. Description of the Related Art

Recently, the degree of integration of semiconductor devices has been improved. In a semiconductor apparatus in which a stack of high-density semiconductor devices is encapsulated in a small and thin package, failure, e.g., cracking or malfunction of the package may occur due to heat generated during operation of the semiconductor device.

As a solution to solve problems due to heat generation, a heatsink formed of a heat dissipation material, e.g., a metal bonded to a semiconductor package upon molding of an epoxy resin for encapsulation has been considered. However, such a heatsink can only be used in some packages such as a fine pitch ball grid array (FBGA) and a quad flat package (QFP) and may have problems of great expense and reduction in productivity due to the need for additional assembly processes. Therefore, there has been urgent demand for an epoxy resin material for encapsulation of semiconductor devices, which has high thermal conductivity and thus good heat dissipation capacity.

### SUMMARY

Embodiments are directed to an epoxy resin composition for encapsulation of semiconductor devices, the composition including an epoxy resin; a curing agent; inorganic fillers; and a curing catalyst, wherein the epoxy resin includes a compound represented by Formula 1:

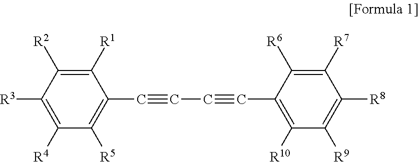

R¹, R², R³, R⁴, R⁵, R⁶, R⁷, R⁸, R⁹, and R¹⁰ are each independently hydrogen, a substituted or unsubstituted C₁ to C₂₀ alkyl group, a substituted or unsubstituted C₁ to C₂₀ alkoxy group, a hydroxyl group, an amino group, a nitro group, a cyano group, a substituted or unsubstituted C₁ to C₂₀ alkenyl group, a substituted or unsubstituted C₁ to C₂₀ haloalkyl group, a substituted or unsubstituted C₆ to C₃₀ aryl group, a substituted or unsubstituted C₃ to C₃₀ heteroaryl group, a substituted or unsubstituted C₃ to C₁₀ cycloalkyl group, a substituted or unsubstituted C₃ to C₁₀ heterocycloalkyl group, a substituted or unsubstituted C₇ to C₃₀ arylalkyl group, a substituted or unsubstituted C₁ to C₃₀ heteroalkyl group, or a compound represented by Formula 2:

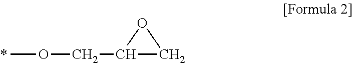

* is a linking site to an element, at least one of R¹, R², R³, R⁴, and R⁵ is represented by Formula 2, and at least one of R⁶, R⁷, R⁸, R⁹, and R¹⁰ is represented by Formula 2.

In Formula 1, R³ may be a compound represented by Formula 2 and R¹, R², R⁴, and R⁵ may each independently be hydrogen, a substituted or unsubstituted C₁ to C₂₀ alkyl group, or a substituted or unsubstituted C₁ to C₂₀ alkoxy group, and R⁸ may be a compound represented by Formula 2 and R⁶, R⁷, R⁹, and R¹⁰ may each independently be hydrogen, a substituted or unsubstituted C₁ to C₂₀ alkyl group, or a substituted or unsubstituted C₁ to C₂₀ alkoxy group.

The epoxy resin represented by Formula 1 may include a compound represented by Formula 1-1, a compound represented by Formula 1-2, a compound represented by Formula 1-3, a compound represented by Formula 1-4, or a compound represented by

### Formula 1-5:

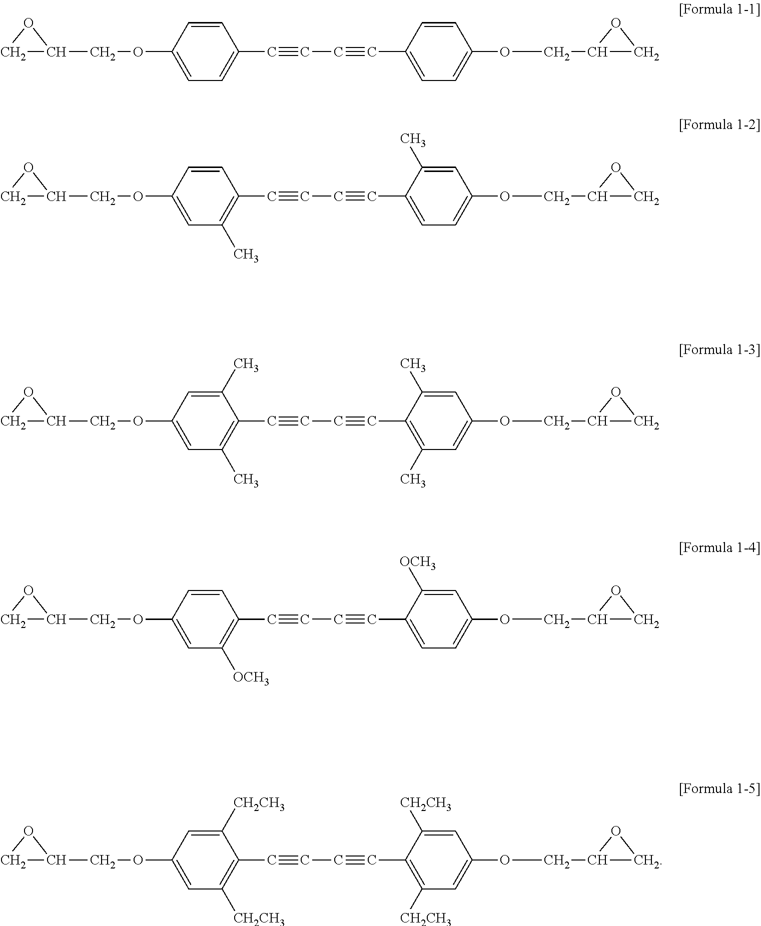 [SMILES: C(C#Cc1ccc(OCC2CO2)cc1)#Cc1ccc(OCC2CO2)cc1 ; Cc1cc(OCC2CO2)ccc1C#CC#Cc1ccc(OCC2CO2)cc1C ; Cc1cc(OCC2CO2)cc(C)c1C#CC#Cc1c(C)cc(OCC2CO2)cc1C ; COc1cc(OCC2CO2)ccc1C#CC#Cc1ccc(OCC2CO2)cc1OC ; CCc1cc(OCC2CO2)cc(CC)c1C#CC#Cc1c(CC)cc(OCC2CO2)cc1CC]

The epoxy resin represented by Formula 1 may be present in an amount of 0.1 wt % to 17 wt %, based on a total weight of the epoxy resin composition.

The the inorganic fillers may include alumina.

The epoxy resin may include, based on a total weight of the epoxy resin composition, 2 wt % to 17 wt % of the epoxy resin, 0.5 wt % to 13 wt % of the curing agent, 50 wt % to 95 wt % of the inorganic fillers, and 0.01 wt % to 5 wt % of the curing catalyst.

The embodiments may be realized by providing a semiconductor device encapsulated using the epoxy resin composition.

In Formula 1, R³ may be a compound represented by Formula 2 and R¹, R², R⁴, and R⁵ may each independently be hydrogen, a substituted or unsubstituted C₁ to C₂₀ alkyl group, or a substituted or unsubstituted C₁ to C₂₀ alkoxy group, and R⁸ may be a compound represented by Formula 2 and R⁶, R⁷, R⁹, and R¹⁰ may each independently be hydrogen, a substituted or unsubstituted C₁ to C₂₀ alkyl group, or a substituted or unsubstituted C₁ to C₂₀ alkoxy group.

The epoxy resin represented by Formula 1 may include a compound represented by Formula 1-1, a compound represented by Formula 1-2, a compound represented by Formula 1-3, a compound represented by Formula 1-4, or a compound represented by Formula 1-5:

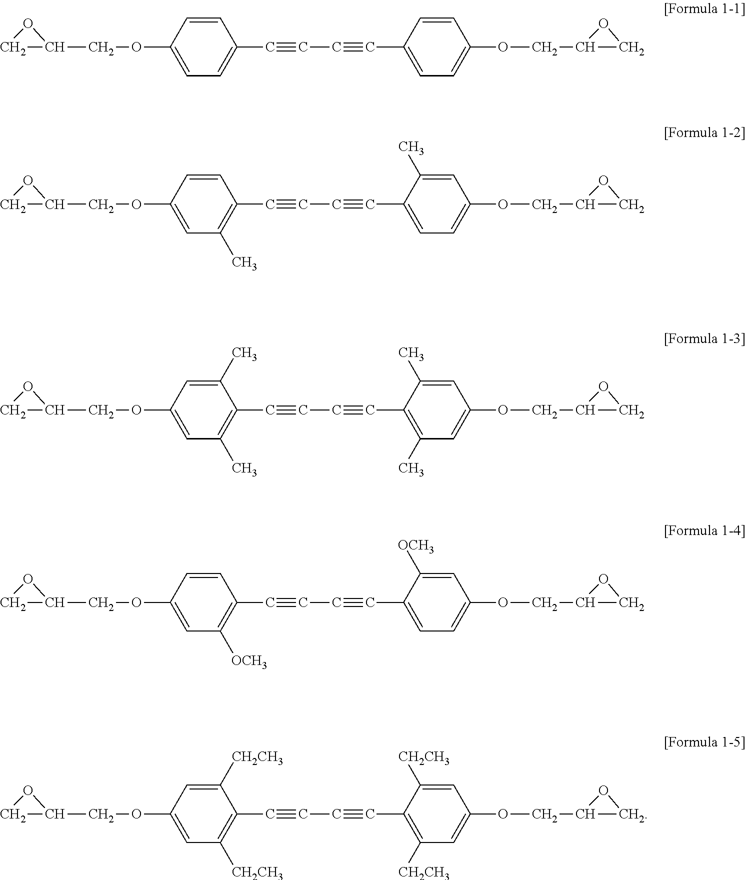 [SMILES: C(C#Cc1ccc(OCC2CO2)cc1)#Cc1ccc(OCC2CO2)cc1 ; Cc1cc(OCC2CO2)ccc1C#CC#Cc1ccc(OCC2CO2)cc1C ; Cc1cc(OCC2CO2)cc(C)c1C#CC#Cc1c(C)cc(OCC2CO2)cc1C ; COc1cc(OCC2CO2)ccc1C#CC#Cc1ccc(OCC2CO2)cc1OC ; CCc1cc(OCC2CO2)cc(CC)c1C#CC#Cc1c(CC)cc(OCC2CO2)cc1CC]

The epoxy resin represented by Formula 1 may be present in an amount of 0.1 wt % to 17 wt %, based on a total weight of the epoxy resin composition.

The inorganic fillers may include alumina.

The epoxy resin may include, based on a total weight of the epoxy resin composition 2 wt % to 17 wt % of the epoxy resin, 0.5 wt % to 13 wt % of the curing agent, 50 wt % to 95 wt % of the inorganic fillers, and 0.01 wt % to 5 wt % of the curing catalyst.

### DETAILED DESCRIPTION

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey exemplary implementations to those skilled in the art.

In the drawing figures, the dimensions of layers and regions may be exaggerated for clarity of illustration. It will also be understood that when a layer or element is referred to as being “on” another layer or substrate, it can be directly on the other layer or substrate, or intervening layers may also be present. Further, it will be understood that when a layer is referred to as being “under” another layer, it can be directly under, and one or more intervening layers may also be present. In addition, it will also be understood that when a layer is referred to as being “between” two layers, it can be the only layer between the two layers, or one or more intervening layers may also be present. Like reference numerals refer to like elements throughout. As used herein, the term “or” is not an exclusive term, e.g., “A or B” would include A, B, or A and B

As used herein, the singular forms “a”, “an”, and “the” are intended to include the plural forms as well, unless the context clearly indicates otherwise.

As used herein to represent a specific numerical range, the expression “X to Y” means “greater than or equal to X and less than or equal to Y”.

As used herein, “substituted” in the expression “substituted or unsubstituted” means that at least one hydrogen atom of a corresponding functional group is substituted with a hydroxyl group, an amino group, a nitro group, a cyano group, a C₁ to C₂₀ alkyl group, a substituted or unsubstituted C₁ to C₂₀ alkoxy group, a C₁ to C₂₀ haloalkyl group, a C₆ to C₃₀ aryl group, a C₃ to C₃₀ heteroaryl group, a C₃ to C₁₀ cycloalkyl group, a C₃ to C₁₀ heterocycloalkyl group, a C₇ to C₃₀ arylalkyl group, or a C₁ to C₃₀ heteroalkyl group.

In order to impart high thermal conductivity to an epoxy resin composition for encapsulation of semiconductor devices, relatively large quantities of inorganic fillers may be required. However, the use of inorganic fillers in large quantities can cause increase in viscosity of the composition and reduction in fluidity of the composition, which may result in difficulty in forming a semiconductor package.

Use of alumina, which may be an inorganic filler having relatively high thermal conductivity, may be considered. However, since an epoxy resin included in the composition may have a very low thermal conductivity of about 0.2 W/m·K, there may be a limitation in increasing thermal conductivity of the composition even with the use of alumina.

In accordance with some embodiments, an epoxy resin composition for encapsulation of semiconductor devices may include an epoxy resin, a curing agent, inorganic fillers, and a curing catalyst, wherein the epoxy resin may include an epoxy resin represented by Formula 1. The epoxy resin represented by Formula 1 may help improve heat dissipation capacity of the composition due to high thermal conductivity thereof and may help improve fluidity of the composition due to low viscosity thereof. As a result, the epoxy resin composition according to some embodiments may help suppress heat-induced malfunction or failure of a semiconductor package and may help improve reliability of the semiconductor package by maintaining the surface temperature of a semiconductor at low levels. In addition, the epoxy resin represented by Formula 1 may help reduce moisture absorption of the composition while reducing solder joint stress.

### Epoxy Resin

The epoxy resin may include an epoxy resin represented by Formula 1. The epoxy resin represented by Formula 1 may help improve heat dissipation capacity of the composition due to high thermal conductivity thereof and may help improve fluidity and processability of the composition due to low viscosity thereof.

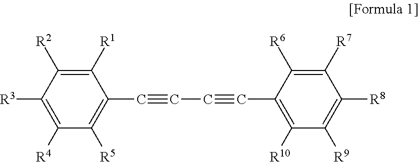

In Formula 1, R¹, R², R³, R⁴, R⁵, R⁶, R⁷, R⁸, R⁹, and R¹⁰ may each independently be or include, e.g., hydrogen, a substituted or unsubstituted C₁ to C₂₀ alkyl group, a substituted or unsubstituted C₁ to C₂₀ alkoxy group, a hydroxyl group, an amino group, a nitro group, a cyano group, a substituted or unsubstituted C₁ to C₂₀ alkenyl group, a substituted or unsubstituted C₁ to C₂₀ haloalkyl group, a substituted or unsubstituted C₆ to C₃₀ aryl group, a substituted or unsubstituted C₃ to C₃₀ heteroaryl group, a substituted or unsubstituted C₃ to C₁₀ cycloalkyl group, a substituted or unsubstituted C₃ to C₁₀ heterocycloalkyl group, a substituted or unsubstituted C₇ to C₃₀ arylalkyl group, a substituted or unsubstituted C₁ to C₃₀ heteroalkyl group, or a compound represented by Formula 2.

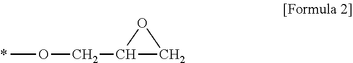

In Formula 2, * is a linking site to an element.

At least one of R¹, R², R³, R⁴, and R⁵ may be the compound represented by Formula 2, and at least one of R⁶, R⁷, R⁸, R⁹, and R¹⁰ may be the compound represented by Formula 2.

In an implementation, among R¹, R², R³, R⁴, and R⁵, R³ may be represented by Formula 2 and R¹, R², R⁴, and R⁵ are may each independently be, e.g., hydrogen, a substituted or unsubstituted C₁ to C₂₀ alkyl group, or a substituted or unsubstituted C₁ to C₂₀ alkoxy group, e.g., hydrogen, an unsubstituted C₁ to C₅ alkyl group, or a substituted or unsubstituted C₁ to C₅ alkoxy group.

In an implementation, among R⁶, R⁷, R⁸, R⁹, and R¹⁰, R⁸ may be represented by Formula 2 and R⁶, R⁷, R⁹, and R¹⁰ may each independently be, e.g., hydrogen, a substituted or unsubstituted C₁ to C₂₀ alkyl group, or a substituted or unsubstituted C₁ to C₂₀ alkoxy group, e.g., hydrogen, an unsubstituted C₁ to C₅ alkyl group, or a substituted or unsubstituted C₁ to C₅ alkoxy group.

In an implementation, the epoxy resin represented by Formula 1 may include, e.g., a compound represented by Formula 1-1, a compound represented by Formula 1-2, a compound represented by Formula 1-3, a compound represented by Formula 1-4, or a compound represented by Formula 1-5.

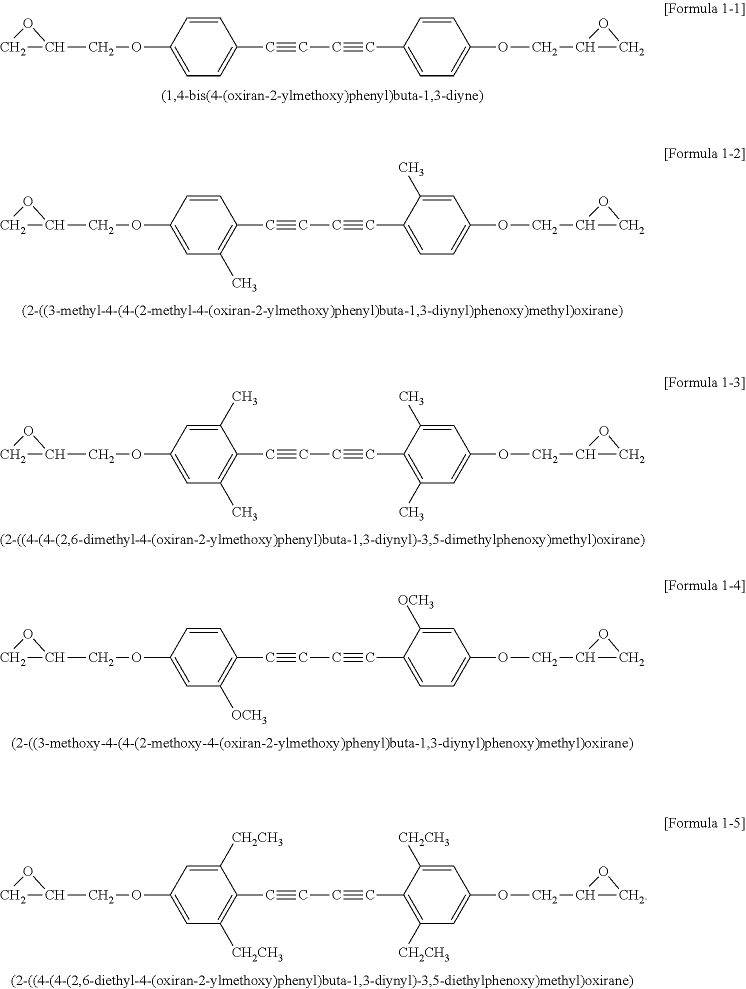 [SMILES: C(C#Cc1ccc(OCC2CO2)cc1)#Cc1ccc(OCC2CO2)cc1 ; Cc1cc(OCC2CO2)ccc1C#CC#Cc1ccc(OCC2CO2)cc1C ; Cc1cc(OCC2CO2)cc(C)c1C#CC#Cc1c(C)cc(OCC2CO2)cc1C ; COc1cc(OCC2CO2)ccc1C#CC#Cc1ccc(OCC2CO2)cc1OC ; CCc1cc(OCC2CO2)cc(CC)c1C#CC#Cc1c(CC)cc(OCC2CO2)cc1CC]

As the epoxy resin represented by Formula 1, these compounds may be used alone or in combination thereof in the epoxy resin composition. The epoxy resin represented by Formula 1 may be present in an amount of 0.1 wt % to 17 wt %, e.g., 2 wt % to 17 wt % or 2 wt % to 10 wt %, based on a total weight of the epoxy resin composition. Within these ranges, the composition may have improved heat dissipation capacity without reduction in curability.

The epoxy resin represented by Formula 1 may be prepared, e.g., by an epoxy resin preparation method with reference to Formula 1.

In an implementation, the epoxy resin of the epoxy resin composition may consist solely of the epoxy resin represented by Formula 1. In an implementation, the epoxy resin represented by Formula 1 may be present in an amount of 100 wt %, based on the total weight of the epoxy resin contained in the epoxy resin composition.

In an implementation, the epoxy resin composition may further include an epoxy resin other than the epoxy resin represented by Formula 1 without affecting the desired benefits described herein. For descriptive convenience, the epoxy resin represented by Formula 1 will be referred to as a first epoxy resin, and the epoxy resin other than the epoxy resin represented by Formula 1 will be referred to as a second epoxy resin.

The second epoxy resin may be an epoxy resin containing at least two epoxy groups per molecule and may include, e.g., a bisphenol A epoxy resin, a bisphenol F epoxy resin, a phenol novolac epoxy resin, a tert-butyl catechol epoxy resin, a naphthalene epoxy resin, a glycidyl amine epoxy resin, a cresol novolac epoxy resin, a biphenyl epoxy resin, a phenol aralkyl epoxy resin, a linear aliphatic epoxy resin, a cycloaliphatic epoxy resin, a heterocyclic epoxy resin, a spirocyclic epoxy resin, a cyclohexanedimethanol epoxy resin, a trimethylol epoxy resin, a halogenated epoxy resin, or the like. As the second epoxy resin, these epoxy resins may be used alone or as a mixture thereof.

The epoxy resin may be present in an amount of 2 wt % to 17 wt %, e.g., 2 wt % to 10 wt %, based on the total weight of the epoxy resin composition. Within these ranges, the composition may avoid reduction in curability.

### Curing Agent

The curing agent may include: a polyhydric phenol compound, e.g., a polyfunctional phenolic resin, a phenol aralkyl phenolic resin, a phenol novolac phenolic resin, a xylok phenolic resin, a cresol novolac phenolic resin, a naphthol phenolic resin, a terpene phenolic resin, a dicyclopentadiene phenolic resin, a novolac phenolic resin synthesized from bisphenol A and resol, tris(hydroxyphenyl) methane, or dihydroxybiphenyl; an acid anhydride, e.g., maleic anhydride or phthalic anhydride; or an aromatic amine, e.g., metaphenylenediamine, diaminodiphenylmethane, or diaminodiphenylsulfone. Preferably, the curing agent may be a xylok phenolic resin or a phenol aralkyl phenolic resin.

The curing agent may be present in an amount of 0.5 wt % to 13 wt %, based on the total weight of the epoxy resin composition. Within this range, the composition may avoid reduction in curability.

### Inorganic Fillers

The inorganic fillers may serve to help improve mechanical properties of the epoxy resin composition while ensuring low stress in the epoxy resin composition. In an implementation, the inorganic fillers may help increase thermal conductivity and heat dissipation capacity of the epoxy resin composition, may help improve fluidity of the epoxy resin composition, and may help reduce thermal expansion and moisture absorption of the epoxy resin composition.

The inorganic fillers may include, e.g., fused silica, crystalline silica, calcium carbonate, magnesium carbonate, alumina, magnesia, clay, talc, calcium silicate, titanium oxide, antimony oxide, or glass fiber.

In an implementation, the inorganic fillers may include alumina. The alumina may have a thermal conductivity of about 25 W/m·K to 30 W/m·K and may be effective in increasing thermal conductivity of the composition.

The alumina may have a spherical or aspherical shape. If the alumina has a spherical shape, the composition may have improved fluidity. The alumina may have an average particle diameter (D₅₀) of 0.5 μm to 50 μm, e.g., 0.5 μm to 30 μm. Within these ranges, the composition may have good properties in terms of fluidity and thermal conductivity. In an implementation, the alumina may include, e.g., a mixture of two types of alumina having different average particle diameters (D₅₀). In an implementation, the alumina may be a mixture in which a first type of alumina and a second type of alumina are present in a weight ratio of 1:1 to 10:1, wherein the first type of alumina may have a greater average particle diameter (D₅₀) than the second type of alumina. The alumina may be coated with the epoxy resin or the curing agent prior to being incorporated into the composition, as needed.

The content of the inorganic fillers in the composition may be varied depending on properties required for the composition, e.g., thermal conductivity, moldability, reduced internal stress, and strength at high temperatures. In an implementation, the inorganic fillers may be present in an amount of 50 wt % to 95 wt %, e.g., 70 wt % to 95 wt % or 85 wt % to 95 wt %, based on a total weight of the epoxy resin composition. Within these ranges, the epoxy resin composition may have good properties in terms of flame retardancy, fluidity, and reliability.

### Curing Catalyst

The curing catalyst may be, e.g., a tertiary amine compound, an organometallic compound, an organophosphorus compound, an imidazole compound, or a boron compound. The tertiary amine compound may include, e.g., benzyldimethylamine, triethanolamine, triethylenediamine, diethylaminoethanol, tri (dimethylaminomethyl) phenol, 2,2-(dimethylaminomethyl) phenol, 2,4,6-tris(diaminomethyl) phenol, tri-2-ethyl hexanoate, or the like. The organometallic compound may include, e.g., chromium acetylacetonate, zinc acetylacetonate, nickel acetylacetonate, or the like. The organophosphorus compound may include, e.g., triphenylphosphine, tris-4-methoxyphosphine, triphenylphosphine-triphenylborane, or a triphenylphosphine-1,4-benzoquinone adduct, or the like. The imidazole compound may include, e.g., 2-methylimidazole, 2-phenylimidazole, 2-aminoimidazole, 2-methyl-1-vinylimidazole, 2-ethyl-4-methylimidazole, 2-heptadecyl imidazole, or the like. The boron compound may include, e.g., triphenylphosphine tetraphenyl borate, a tetraphenylboron salt, trifluoroborane-n-hexylamine, trifluoroborane monoethylamine, tetrafluoroborane triethylamine, tetrafluoroborane amine, or the like. In an implementation, 1,5-diazabicyclo[4.3.0]non-5-ene (DBN), 1,8-diazabicyclo[5.4.0]undec-7-ene (DBU), or a phenol novolac resin salt may be used as the curing catalyst.

The curing catalyst may be used in the form of an adduct prepared by pre-reacting the curing catalyst with the epoxy resin or the curing agent.

The curing catalyst may be present in an amount of 0.01 wt % to 5 wt %, based on a total weight of the epoxy resin composition. Within this range, the curing catalyst may promote curing of the composition without sacrificing fluidity of the composition.

The epoxy resin composition may further include an additive used in some epoxy resin compositions for encapsulation of semiconductor devices. In an implementation, the additive may include, e.g., a coupling agent, a release agent, a colorant, a stress relaxation agent, a crosslinking enhancer, or a leveling agent.

The coupling agent may serve to increase interfacial strength between the epoxy resin and the inorganic fillers through reaction with the epoxy resin and the inorganic fillers, and may be, e.g., a silane coupling agent. The silane coupling agent may include any silane coupling agent that may help increase interfacial strength between the epoxy resin and the inorganic fillers through reaction with the epoxy resin and the inorganic fillers. The silane coupling agent may include, e.g., epoxy silane, amino silane, ureido silane, mercapto silane, alkyl silane, or the like. These may be used alone or in combination thereof. The coupling agent may be present in an amount of 0.01 wt % to 5 wt %, e.g., 0.05 wt % to 3 wt %, based on the total weight of the epoxy resin composition for encapsulation of semiconductor devices. Within this range, a cured product of the epoxy resin composition may have enhanced strength.

The release agent may include, e.g., paraffin wax, ester wax, higher fatty acid, a metallic salt of higher fatty acid, natural fatty acid, or a metallic salt of natural fatty acid. The release agent may be present in an amount of 0.1 wt % to 1 wt %, based on a total weight of the epoxy resin composition.

The colorant may include, e.g., carbon black. The colorant may be present in an amount of 0.1 wt % to 1 wt %, based on the total weight of the epoxy resin composition.

The stress relaxation agent may include, e.g., modified silicone oil, a silicone elastomer, a silicone powder, or a silicone resin. The stress relaxation agent may be present in an amount of 2 wt % or less, e.g., 1 wt % or less or 0.1 wt % to 1 wt %, based on the total weight of the epoxy resin composition.

The additive may be present in an amount of 0.1 wt % to 5 wt %, e.g., 0.1 wt % to 3 wt %, based on a total weight of the epoxy resin composition.

The epoxy resin composition may be prepared through a process in which the aforementioned components are uniformly mixed in a Henschel mixer or a Lödige mixer, followed by melt-kneading in a roll mill or a kneader at a temperature of 90° C. to 120° C., and then the resultant may be subjected to cooling and pulverization.

A semiconductor device according to some embodiments may be encapsulated using the epoxy resin composition for encapsulation of semiconductor devices according to some embodiments. The semiconductor device may be encapsulated with the epoxy resin composition by any suitable method known in the art, such as transfer molding, injection molding, casting, and compression molding. In an implementation, the semiconductor device may be encapsulated with the epoxy resin composition by low-pressure transfer molding. In another implementation, the semiconductor device may be encapsulated with the epoxy resin composition by compression molding.

The following Examples and Comparative Examples are provided in order to highlight characteristics of one or more embodiments, but it will be understood that the Examples and Comparative Examples are not to be construed as limiting the scope of the embodiments, nor are the Comparative Examples to be construed as being outside the scope of the embodiments. Further, it will be understood that the embodiments are not limited to the particular details described in the Examples and Comparative Examples.

### Preparative Example: Preparation and Analysis of Epoxy Resin

Epoxy resins represented by Formulas 1-1, 1-2, 1-3, 1-4, and 1-5 were prepared as follows:

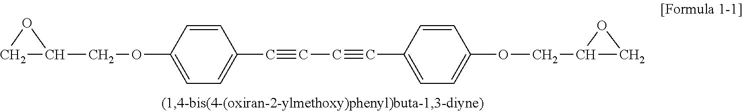 [SMILES: C(C#Cc1ccc(OCC2CO2)cc1)#Cc1ccc(OCC2CO2)cc1]

In a 1,000 mL reactor, 500 mL of dimethylformamide as a solvent, 4-iodophenol (30 g, 136.2 mmol), propiolic acid (18.5 mL, 300 mmol), and Et₃N (70 mL) were placed along with PdCl₂(PPh₃)₂ (5 g, 7.1 mmol), CuI (1.7 g, 9.0 mmol), and Ag₂CO₃ (83 g, 300 mmol) as catalysts, followed by reaction at 130° C. for 24 hours, and then the solvent was dried, followed by purification of the reaction product through a silica gel column. A solvent used in purification through the silica gel column was a mixture of ethyl acetate and hexane (1:6). After purification through the silica gel column, 17 g of a bright yellow compound powder obtained by removing the solvent under reduced pressure was placed in a 500 mL reactor along with benzyltrimethylammonium bromide (5.0 g, 21.7 mmol) and an excess of epichlorohydrin (300 mL), followed by reaction at 110° C. for 1 hour, and then NaOH (6 g, 145.0 mmol) was added, followed by reaction for 2 hours. After completion of the reaction, the solvent was removed under reduced pressure, followed by purifying the reaction product with deionized water, thereby obtaining 21 g of a bright yellow powder of the compound represented by Formula 1-1 at a yield of 42%. The powder was confirmed to be the compound represented by Formula 1-1 by NMR, LC-MS, and elemental analysis. ¹H NMR (400 MHZ, CDCl₃) 7.53 (m, 2H), 7.01 (m, 4H), 4.40 (m, 2H), 3.88, (m, 2H), 3.33 (m, 2H), 2.85 (m, 2H), 2.71 (m, 2H)) ppm; ¹³C NMR (100 MHz, CDCl₃) 159.1, 133.9, 114.9, 112.6, 81.3, 72.6, 69.9, 49.9, 43.3 ppm; LC-MS m/z=346 (M⁺); Anal. Calcd for C₂₂H₁₈O₄: C, 76.29; H, 5.24; Found: C, 76.54; H, 5.39

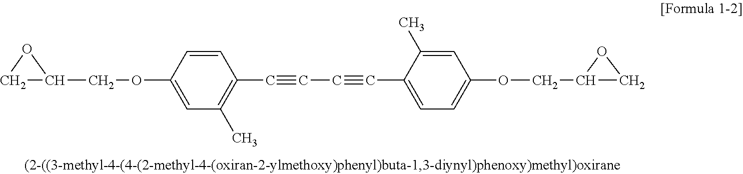 [SMILES: Cc1cc(OCC2CO2)ccc1C#CC#Cc1ccc(OCC2CO2)cc1C]

In a 1,000 mL reactor, 500 mL of dimethylformamide as a solvent, 4-iodo-3-methylphenol (32 g, 136.2 mmol), propiolic acid (18.5 mL, 300 mmol), and Et₃N (70 mL) was placed along with PdCl₂(PPh₃)₂ (5 g, 7.1 mmol), CuI (1.7 g, 9.0 mmol), and Ag₂CO₃ (83 g, 300 mmol) as catalysts, followed by reaction at 130° C. for 24 hours, and then the solvent was dried, followed by purification of the reaction product through a silica gel column. A solvent used in purification through the silica gel column was a mixture of ethyl acetate and hexane (1:6). After purification through the silica gel column, 18 g of a bright yellow compound powder obtained by removing the solvent under reduced pressure was placed in a 500 mL reactor along with benzyltrimethylammonium bromide (5.0 g, 21.7 mmol) and an excess of epichlorohydrin (300 mL), followed by reaction at 110° C. for 1 hour, and then NaOH (6 g, 145.0 mmol) was added, followed by reaction for 2 hours. After completion of the reaction, the solvent was removed under reduced pressure, followed by purifying the reaction product with deionized water, thereby obtaining 20 g of a bright yellow powder of the compound represented by Formula 1-2 at a yield of 40%. The powder was confirmed to be the compound represented by Formula 1-2 by NMR, LC-MS, and elemental analysis. 1H NMR (400 MHZ, CDCl₃) 7.19 (m, 2H), 6.57-6.54 (m, 4H), 4.20 (m, 2H), 3.95, (m, 2H), 3.05 (m, 2H), 2.63 (m, 2H), 2.35 (m, 2H), 2.33 (s, 6H) ppm; ¹³C NMR (100 MHz, CDCl₃) 157.1, 142.8, 132.8, 115.2, 112.8, 111.0, 77.0, 74.7, 69.5, 50.0, 44.2, 17.2 ppm; LC-MS m/z=374 (M⁺); Anal. Calcd for C₂₄H₂₂O₄: C, 76.99; H, 5.92; Found: C, 76.89; H, 5.74

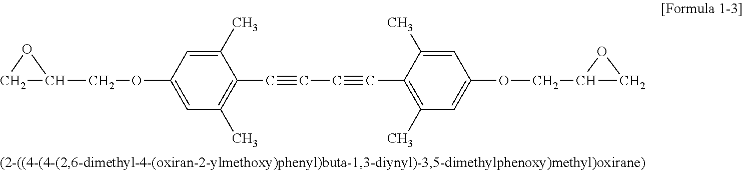

In a 1,000 mL reactor, 500 mL of dimethylformamide as a solvent, 4-iodo-3,5-dimethylphenol (34 g, 136.2 mmol), propiolic acid (18.5 mL, 300 mmol), and Et₃N (70 mL) was placed along with PdCl₂(PPh₃)₂ (5 g, 7.1 mmol), CuI (1.7 g, 9.0 mmol), and Ag₂CO₃ (83 g, 300 mmol) as catalysts, followed by reaction at 130° C. for 24 hours, and then the solvent was dried, followed by purification of the reaction product through a silica gel column. A solvent used in purification through the silica gel column was a mixture of ethyl acetate and hexane (1:6). After purification through the silica gel column, 18 g of a bright yellow compound powder obtained by removing the solvent under reduced pressure was placed in a 500 mL reactor along with benzyltrimethylammonium bromide (5.0 g, 21.7 mmol) and an excess of epichlorohydrin (300 mL), followed by reaction at 110° C. for 1 hour, and then NaOH (6 g, 145.0 mmol) was added, followed by reaction for 2 hours. After completion of the reaction, the solvent was removed under reduced pressure, followed by purifying the reaction product with deionized water, thereby obtaining 20 g of a bright yellow powder of the compound represented by Formula 1-3 at a yield of 39%. The powder was confirmed to be the compound represented by Formula 1-3 by NMR, LC-MS, and elemental analysis. 1H NMR (400 MHZ, CDCl₃) 6.35 (m, 4H), 4.20 (m, 2H), 3.95, (m, 2H), 3.05 (m, 2H), 2.63 (m, 2H), 2.38 (m, 2H), 2.35 (s, 12H) ppm; ¹³C NMR (100 MHz, CDCl₃) 157.1, 142.5, 113.2, 110.1, 109.9, 77.0, 74.7, 69.5, 50.0, 44.2, 17.4 ppm; LC-MS m/z=402 (M⁺); Anal. Calcd for C₂₆H₂₆O₄: C, 77.59; H, 6.51; Found: C, 77.81; H, 6.58

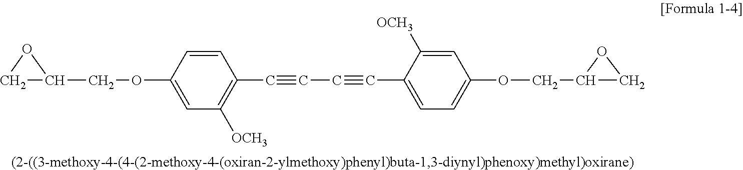

In a 1,000 mL reactor, 500 mL of dimethylformamide as a solvent, 4-iodo-3-methoxyphenol (34 g, 136.2 mmol), propiolic acid (18.5 mL, 300 mmol), and Et₃N (70 mL) was placed along with PdCl₂(PPh₃)₂ (5 g, 7.1 mmol), CuI (1.7 g, 9.0 mmol), and Ag₂CO₃ (83 g, 300 mmol) as catalysts, followed by reaction at 130° C. for 24 hours, and then the solvent was dried, followed by purification of the reaction product through a silica gel column. A solvent used in purification through the silica gel column was a mixture of ethyl acetate and hexane (1:6). After purification through the silica gel column, 18 g of a bright yellow compound powder obtained by removing the solvent under reduced pressure was placed in a 500 mL reactor along with benzyltrimethylammonium bromide (5.0 g, 21.7 mmol) and an excess of epichlorohydrin (300 mL), followed by reaction at 110° C. for 1 hour, and then NaOH (6 g, 145.0 mmol) was added, followed by reaction for 2 hours. After completion of the reaction, the solvent was removed under reduced pressure, followed by purifying the reaction product with deionized water, thereby obtaining 20 g of a bright yellow powder of the compound represented by Formula 1-4 at a yield of 38%. The powder was confirmed to be the compound represented by Formula 1-4 by NMR, LC-MS, and elemental analysis. 1H NMR (400 MHZ, CDCl₃) 7.20 (s, 2H), 6.32-6.25 (m, 4H), 4.20 (m, 2H), 3.95, (m, 2H), 3.73 (s, 6H), 3.05 (m, 2H), 2.63 (m, 2H), 2.35 (m, 2H) ppm; ¹³C NMR (100 MHZ, CDCl₃) 164.01, 158.1, 142.8, 133.9, 133.8, 106.3, 1.6.2, 103.5, 100.1, 100.0, 77.0, 74.7, 69.5, 55.3, 50.0, 44.2 ppm; LC-MS m/z=408 (M⁺); Anal. Calcd for C₂₄H₂₂O₆: C, 70.92; H, 5.46; Found: C, 70.91; H, 5.71.

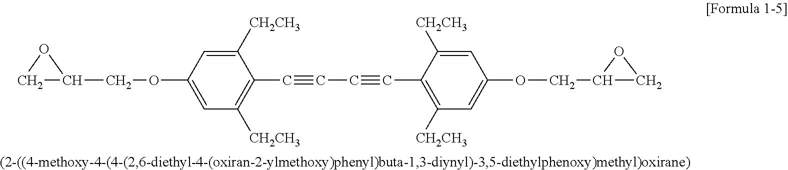

In a 1,000 mL reactor, 500 mL of dimethylformamide as a solvent, 3,5-diethyl-4-iodophenol (38 g, 136.2 mmol), propiolic acid (18.5 mL, 300 mmol), and Et₃N (70 mL) was placed along with PdCl₂(PPh₃)₂ (5 g, 7.1 mmol), CuI (1.7 g, 9.0 mmol), and Ag₂CO₃ (83 g, 300 mmol) as catalysts, followed by reaction at 130° C. for 24 hours, and then the solvent was dried, followed by purification of the reaction product through a silica gel column. A solvent used in purification through the silica gel column was a mixture of ethyl acetate and hexane (1:6). After purification through the silica gel column, 18 g of a bright yellow compound powder obtained by removing the solvent under reduced pressure was placed in a 500 mL reactor along with benzyltrimethylammonium bromide (5.0 g, 21.7 mmol) and an excess of epichlorohydrin (300 mL), followed by reaction at 110° C. for 1 hour, and then NaOH (6 g, 145.0 mmol) was added, followed by reaction for 2 hours. After completion of the reaction, the solvent was removed under reduced pressure, followed by purifying the reaction product with deionized water, thereby obtaining 19 g of a bright yellow powder of the compound represented by Formula 1-5 at a yield of 35%. The powder was confirmed to be the compound represented by Formula 1-4 by NMR, LC-MS, and elemental analysis. ¹H NMR (400 MHZ, CDCl₃) 6.42 (s, 4H), 4.20 (m, 2H), 3.95, (m, 2H), 3.05 (m, 2H), 2.63-2.52 (m, 10H), 2.38 (m, 2H), 1.24 (m, 12H) ppm; ¹³C NMR (100 MHz, CDCl₃) 157.1, 148.6, 148.5, 111.1, 111.0, 109.0, 108.9, 77.0, 74.7, 69.5, 50.0, 44.2, 25.6, 25.4, 14.0 ppm; LC-MS m/z=458 (M⁺); Anal. Calcd for C₃₀H₃₄O₄: C, 78.57; H, 7.47; Found: C, 78.19; H, 7.58.

Details of components used in Examples and Comparative Examples were as follows:
(A) Epoxy resin
(A1) Epoxy resins of Preparative Example (A1-1 (Formula 1-1), A1-2 (Formula 1-2), A1-3 (Formula 1-3), A1-4 (Formula 1-4), A1-5 (Formula 1-5))
(A2) A phenol aralkyl epoxy resin (NC-3000, Nippon Kayaku co., ltd.) (A3) An epoxy resin represented by the following formula:

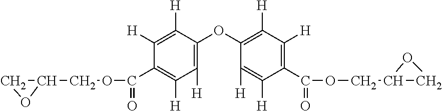 [SMILES: O=C(OCC1CO1)c1ccc(Oc2ccc(C(=O)OCC3CO3)cc2)cc1]

(B) Curing agent
(B1) KPH-F3065 (xylok phenolic resin, Kolon Chemical Co., Ltd.)
(B2) MEH-7851 (phenol aralkyl phenolic resin, Meiwa Corporation)
(C) Curing catalyst: Triphenyl phosphine (Hokko Chemical Co., Ltd.)
(D) Inorganic fillers: A mixture of spherical fused alumina having an average particle diameter (D₅₀) of 20 μm and spherical fused alumina having an average particle diameter (D₅₀) of 0.5 μm (weight ratio: 9:1)
(E) Coupling agent
(E1) Methyltrimethoxysilane (SZ-6070, Dow Corning Corporation)
(E2) KBM-573 (N-phenyl-3-aminopropyltrimethoxysilane, Shinetsu Chemical Co., Ltd.)
(F) Carbon black (MA-600B, Mitsubishi Chemical Co., Ltd.)

### Examples 1 to 6 and Comparative Examples 1 to 4

The aforementioned components were uniformly mixed in amounts (unit: parts by weight) listed in Table 1 in a Henschel mixer (KSM-22, KEUM SUNG MACHINERY Co., Ltd.) at a temperature of 25° C. to 30° C. for 30 minutes, and then melt-kneaded in a continuous kneader at a temperature of up to 110° C. for 30 minutes, followed by cooling to a temperature of 10° C. to 15° C. and pulverization, thereby preparing an epoxy resin composition for encapsulation of semiconductor devices. In Table 1, “-” means that a corresponding component was not used.

Each of the epoxy resin compositions prepared in Examples 1 to 6 and Comparative Examples 1 to 4 was evaluated as to the following properties. Results are shown in Table 1.

(1) Fluidity (unit: inch, spiral flow length): Using a low-pressure transfer molding machine, each of the prepared epoxy resin compositions was injected into a mold for measurement of fluidity under conditions of a mold temperature of 175° C., a load of 70 kgf/cm², an injection pressure of 9 MPa, and a curing time of 90 seconds in accordance with EMMI-1-66, followed by measurement of flow length. A greater flow length indicates better fluidity.

(2) Thermal conductivity (unit: W/m·K): A specimen was prepared using each of the prepared epoxy resin compositions in accordance with ASTM D5470, followed by measurement of thermal conductivity of the specimen at 25° C.

TABLE 1

| | | Example | | | | | | Comparative Example | | | |
|---|---|---|---|---|---|---|---|---|---|---|---|
| | | 1 | 2 | 3 | 4 | 5 | 6 | 1 | 2 | 3 | 4 |
| (A) | (A1-1) | 5.2 | 5.2 | — | — | — | — | — | — | — | — |
| | (A1-2) | — | — | 5.2 | — | — | — | — | — | — | — |
| | (A1-3) | — | — | — | 5.2 | — | — | — | — | — | — |
| | (A1-4) | — | — | — | — | 5.2 | — | — | — | — | — |
| | (A1-5) | — | — | — | — | — | 5.2 | — | — | — | — |
| | (A2) | — | — | — | — | — | — | 5.2 | 5.2 | — | — |
| | (A3) | — | — | — | — | — | — | — | — | 5.2 | 5.2 |
| (B) | (B1) | 4.4 | — | 4.4 | 4.4 | 4.4 | 4.4 | 4.4 | — | 4.4 | — |
| | (B2) | — | 4.4 | — | — | — | — | — | 4.4 | — | 4.4 |
| (C) | | 0.5 | 0.5 | 0.5 | 0.5 | 0.5 | 0.5 | 0.5 | 0.5 | 0.5 | 0.5 |
| (D) | | 89 | 89 | 89 | 89 | 89 | 89 | 89 | 89 | 89 | 89 |
| (E) | (E1) | 0.2 | 0.2 | 0.2 | 0.2 | 0.2 | 0.2 | 0.2 | 0.2 | 0.2 | 0.2 |
| | (E2) | 0.2 | 0.2 | 0.2 | 0.2 | 0.2 | 0.2 | 0.2 | 0.2 | 0.2 | 0.2 |

| | | | | | | | | | | |
|---|---|---|---|---|---|---|---|---|---|---|
| (F) | 0.5 | 0.5 | 0.5 | 0.5 | 0.5 | 0.5 | 0.5 | 0.5 | 0.5 | 0.5 |
| Total | 100 | 100 | 100 | 100 | 100 | 100 | 100 | 100 | 100 | 100 |
| Fluidity | 79 | 74 | 81 | 82 | 80 | 82 | 70 | 68 | 71 | 69 |
| Thermal | 3.7 | 3.5 | 3.5 | 3.4 | 3.6 | 3.2 | 2.9 | 2.7 | 2.7 | 2.6 |
| conductivity | | | | | | | | | | |

As can be seen from Table 1, the epoxy resin compositions of Examples 1 to 6, according to some embodiments, exhibited good moldability due to high fluidity. In addition, the epoxy resin compositions of Examples 1 to 6 exhibited good heat dissipation capacity due to high thermal conductivity and thus were confirmed to be effective in maintaining the surface temperature of a semiconductor device at low levels during operation of the semiconductor device.

Conversely, the compositions of Comparative Examples 1 to 4, free from the epoxy resin represented by Formula 1, exhibited poor heat dissipation capacity due to low thermal conductivity or exhibited poor moldability due to low fluidity.

One of more embodiments may provide an epoxy resin composition for encapsulation of semiconductor devices, which may include an epoxy resin having better properties in terms of thermal conductivity and fluidity than other epoxy resins to secure high thermal conductivity and improved heat dissipation capacity, thereby suppressing heat-induced malfunction or failure of a semiconductor package.

Some semiconductor packages may use spherical aluminum oxide (alumina). Alumina may have a thermal conductivity of about 25 W/m·K to about 30 W/m·K. However, since an epoxy resin included in an epoxy resin composition for encapsulation of semiconductor devices may have a very low thermal conductivity of 0.2 W/m. K, there may be a limitation in increasing thermal conductivity of an encapsulation layer formed of the composition to 6 W/m. K or more even with the use of alumina. In addition, copper, aluminum, or silver particles may have poor insulation performance despite having high thermal conductivity, and aluminum nitride, boron nitride, or silicon carbide fillers may not be able to ensure a high filler loading rate due to poor fluidity thereof despite having relatively good insulation performance. Although many attempts regarding increase in thermal conductivity of an epoxy resin have been made in recent years, commercialization of a semiconductor material encapsulated with a compressed insulating thermosetting resin has not yet been achieved.

In accordance with another aspect of some embodiments, a semiconductor device may be provided.

The semiconductor device may be encapsulated using the epoxy resin composition for encapsulation of semiconductor devices set forth above.

Some embodiments may provide an epoxy resin composition for encapsulation of semiconductor devices, which may have significantly improved heat dissipation capacity due to high thermal conductivity while exhibiting improved fluidity.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. An epoxy resin composition for encapsulation of semiconductor devices, the composition comprising:
an epoxy resin;
a curing agent;
inorganic fillers; and
a curing catalyst,
wherein:
the epoxy resin comprises a compound represented by Formula 1: 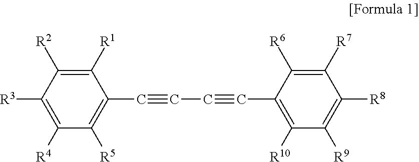
R¹, R², R³, R⁴, R⁵, R⁶, R⁷, R⁸, R⁹, and R¹⁰ are each independently hydrogen, a substituted or unsubstituted C₁ to C₂₀ alkyl group, a substituted or unsubstituted C₁ to C₂₀ alkoxy group, a hydroxyl group, an amino group, a nitro group, a cyano group, a substituted or unsubstituted C₁ to C₂₀ alkenyl group, a substituted or unsubstituted C₁ to C₂₀ haloalkyl group, a substituted or unsubstituted C₆ to C₃₀ aryl group, a substituted or unsubstituted C₃ to C₃₀ heteroaryl group, a substituted or unsubstituted C₃ to C₁₀ cycloalkyl group, a substituted or unsubstituted C₃ to C₁₀ heterocycloalkyl group, a substituted or unsubstituted C₇ to C₃₀ arylalkyl group, a substituted or unsubstituted C₁ to C₃₀ heteroalkyl group, or a compound represented by Formula 2: 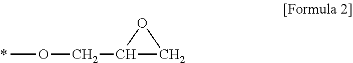
* is a linking site to an element,
at least one of R¹, R², R³, R⁴, and R⁵ is represented by Formula 2, and
at least one of R⁶, R⁷, R⁸, R⁹, and R¹⁰ is represented by Formula 2.

2. The epoxy resin composition as claimed in claim 1, wherein in Formula 1:
R³ is a compound represented by Formula 2 and R¹, R², R⁴, and R⁵ are each independently hydrogen, a substituted or unsubstituted C₁ to C₂₀ alkyl group, or a substituted or unsubstituted C₁ to C₂₀ alkoxy group, and
R⁸ is a compound represented by Formula 2 and R⁶, R⁷, R⁹, and R¹⁰ are each independently hydrogen, a substituted or unsubstituted C₁ to C₂₀ alkyl group, or a substituted or unsubstituted C₁ to C₂₀ alkoxy group.

3. The epoxy resin composition as claimed in claim 1, wherein the epoxy resin represented by Formula 1 comprises a compound represented by Formula 1-1, a compound represented by Formula 1-2, a compound represented by Formula 1-3, a compound represented by Formula 1-4, or a compound represented by Formula 1-5:

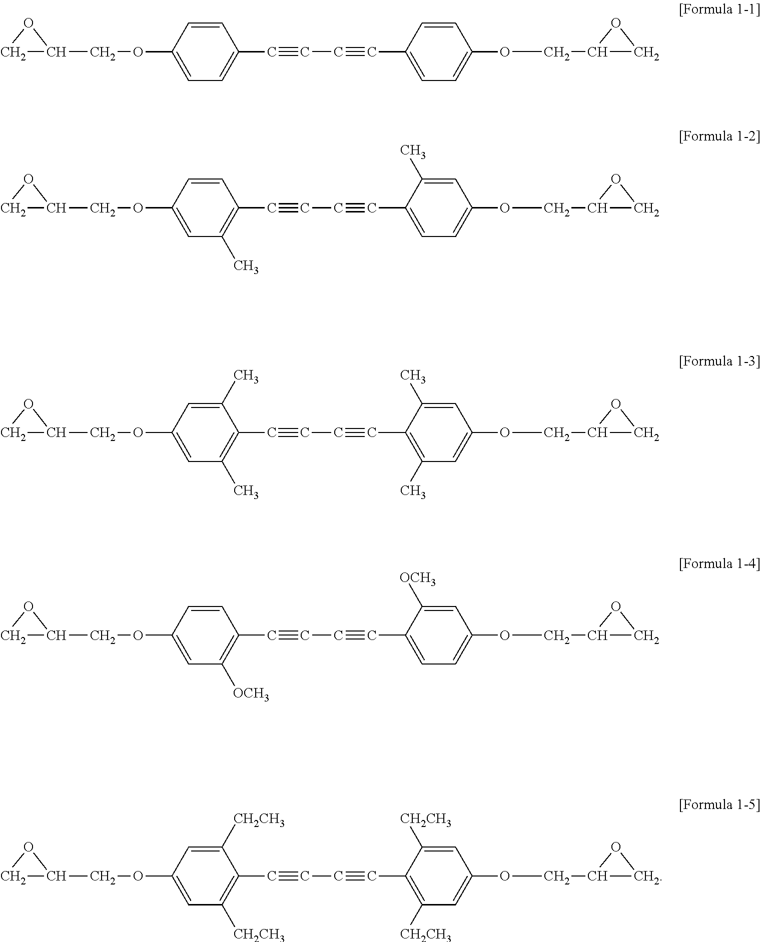 [SMILES: C(C#Cc1ccc(OCC2CO2)cc1)#Cc1ccc(OCC2CO2)cc1 ; Cc1cc(OCC2CO2)ccc1C#CC#Cc1ccc(OCC2CO2)cc1C ; Cc1cc(OCC2CO2)cc(C)c1C#CC#Cc1c(C)cc(OCC2CO2)cc1C ; COc1cc(OCC2CO2)ccc1C#CC#Cc1ccc(OCC2CO2)cc1OC ; CCc1cc(OCC2CO2)cc(CC)c1C#CC#Cc1c(CC)cc(OCC2CO2)cc1CC]

4. The epoxy resin composition as claimed in claim 1, wherein the epoxy resin represented by Formula 1 is present in an amount of 0.1 wt % to 17 wt %, based on a total weight of the epoxy resin composition.

5. The epoxy resin composition as claimed in claim 1, wherein the inorganic fillers comprise alumina.

6. The epoxy resin composition as claimed in claim 1, wherein the epoxy resin comprises, based on a total weight of the epoxy resin composition:
2 wt % to 17 wt % of the epoxy resin;
0.5 wt % to 13 wt % of the curing agent;
50 wt % to 95 wt % of the inorganic fillers; and
0.01 wt % to 5 wt % of the curing catalyst.

7. A semiconductor device encapsulated using the epoxy resin composition as claimed in claim 1.

8. The semiconductor device as claimed in claim 7, wherein in Formula 1:
R³ is a compound represented by Formula 2 and R¹, R², R⁴, and R⁵ are each independently hydrogen, a substituted or unsubstituted C₁ to C₂₀ alkyl group, or a substituted or unsubstituted C₁ to C₂₀ alkoxy group, and
R⁸ is a compound represented by Formula 2 and R⁶, R⁷, R⁹, and R¹⁰ are each independently hydrogen, a substituted or unsubstituted C₁ to C₂₀ alkyl group, or a substituted or unsubstituted C₁ to C₂₀ alkoxy group.

9. The semiconductor device as claimed in claim 7, wherein the epoxy resin represented by Formula 1 comprises a compound represented by Formula 1-1, a compound represented by Formula 1-2, a compound represented by Formula 1-3, a compound represented by Formula 1-4, or a compound represented by Formula 1-5:

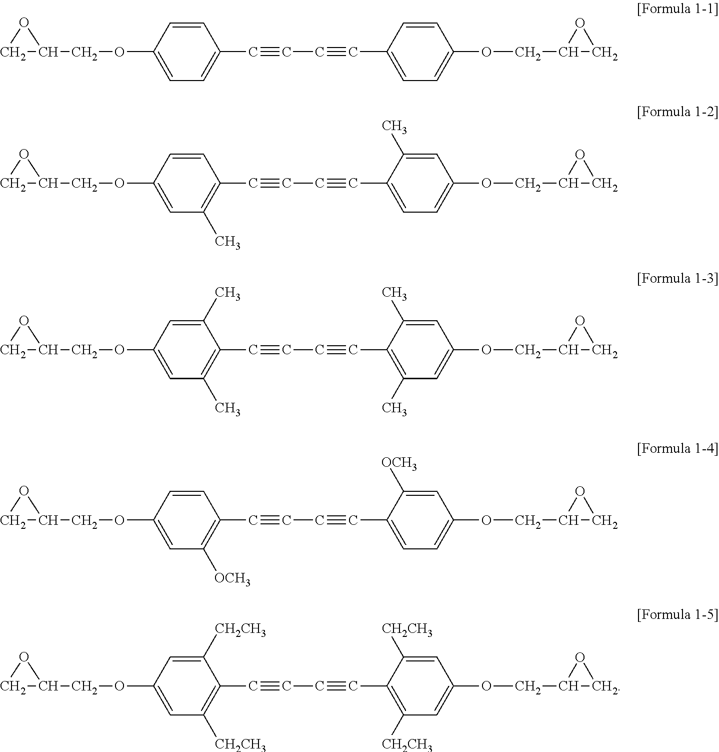 [SMILES: C(C#Cc1ccc(OCC2CO2)cc1)#Cc1ccc(OCC2CO2)cc1 ; Cc1cc(OCC2CO2)ccc1C#CC#Cc1ccc(OCC2CO2)cc1C ; Cc1cc(OCC2CO2)cc(C)c1C#CC#Cc1c(C)cc(OCC2CO2)cc1C ; COc1cc(OCC2CO2)ccc1C#CC#Cc1ccc(OCC2CO2)cc1OC ; CCc1cc(OCC2CO2)cc(CC)c1C#CC#Cc1c(CC)cc(OCC2CO2)cc1CC]

10. The semiconductor device as claimed in claim 7, wherein the epoxy resin represented by Formula 1 is present in an amount of 0.1 wt % to 17 wt %, based on a total weight of the epoxy resin composition.

11. The semiconductor device as claimed in claim 7, wherein the inorganic fillers comprise alumina.

12. The semiconductor device as claimed in claim 7, wherein the epoxy resin comprises, based on a total weight of the epoxy resin composition:
2 wt % to 17 wt % of the epoxy resin;
0.5 wt % to 13 wt % of the curing agent;
50 wt % to 95 wt % of the inorganic fillers; and
0.01 wt % to 5 wt % of the curing catalyst.
